(19) United States
(12) Patent Application Publication
(10) Pub. No.: US 2009/0308739 A1
(43) Pub. Date: Dec. 17, 2009

(54) WAFER PROCESSING DEPOSITION SHIELDING COMPONENTS

(75) Inventors: Martin Lee Riker, Milpitas, CA (US); Maurice E. Ewert, San Jose, CA (US); Anantha K. Subramani, San Jose, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/482,846

(22) Filed: Jun. 11, 2009

Related U.S. Application Data
(60) Provisional application No. 61/073,130, filed on Jun. 17, 2008.
(60) Provisional application No. 61/172,627, filed on Apr. 24, 2009.

(51) Int. Cl. C23C 14/34

(52) U.S. Cl. 204/298.11; 204/298.02

(57) ABSTRACT

Embodiments described herein generally relate to an apparatus and method for uniform sputter depositing of materials into the bottom and sidewalls of high aspect ratio features on a substrate. In one embodiment, a collimator for mechanical and electrical coupling with a shield member positioned between a sputtering target and a substrate support pedestal is provided. The collimator comprises a central region and a peripheral region, wherein the collimator has a plurality of apertures extending therethrough and where the apertures located in the central region have a higher aspect ratio than the apertures located in the peripheral region.

### CROSS-REFERENCE TO RELATED APPLICATIONS

This application claims benefit of U.S. provisional patent application Ser. No. 61/073,130 (Attorney Docket No. 12996L), filed Jun. 17, 2008, and U.S. provisional patent application Ser. No. 61/172,627 (Attorney Docket No. 14278L), filed Apr. 24, 2009, both of which are herein incorporated by reference in their entirety. This application is related to U.S. patent application Ser. No. 12/482,713, filed Jun. 11, 2009 (Attorney Docket No. 12996).

### BACKGROUND

1. Field

Embodiments of the present invention generally relate to an apparatus and method for uniform sputter depositing of materials into the bottom and sidewalls of high aspect ratio features on a substrate.

2. Description of the Related Art

Sputtering, or physical vapor deposition (PVD), is a widely used technique for depositing thin metal layers on substrates in the fabrication of integrated circuits. PVD is used to deposit layers for use as diffusion barriers, seed layers, primary conductors, antireflection coatings, and etch stops. However, with PVD it is difficult to form a uniform, thin film that conforms to the shape of a substrate where a step occurs, such as a via or trench formed in the substrate. In particular, the broad angular distribution of depositing sputtered atoms leads to poor coverage in the bottom and sidewalls of high aspect ratio features, such as vias and trenches.

One technique developed to allow the use of PVD to deposit thin films in the bottom of a high aspect ratio feature is collimator sputtering. A collimator is a filtering plate positioned between a sputtering source and a substrate. The collimator typically has a uniform thickness and includes a number of passages formed through the thickness. Sputtered material must pass through the collimator on its path from the sputtering source to the substrate. The collimator filters out material that would otherwise strike the workpiece at acute angles exceeding a desired angle.

The actual amount of filtering accomplished by a given collimator depends on the aspect ratio of the passages through the collimator. As such, particles traveling on a path approaching normal to the substrate pass through the collimator and are deposited on the substrate. This allows improved coverage in the bottom of high aspect ratio features.

However, certain problems exist with the use of prior art collimators in conjunction with small magnet magnetrons. Use of small magnet magnetrons may produce a highly ionized metal flux, which may be advantageous in filling high aspect ratio features. Unfortunately, PVD with a prior art collimator in combination with a small magnet magnetron provides non-uniform deposition across a substrate. Thicker layers of source material may be deposited in one region of the substrate than in other regions of the substrate. For example, thicker layers may be deposited near the center or the edge of the substrate, depending on the radial positioning of the small magnet. This phenomenon not only leads to non-uniform deposition across the substrate, but it also leads to non-uniform deposition across high aspect ratio feature sidewalls in certain regions of the substrate as well. For instance, a small magnet positioned radially to provide optimum field uniformity in the region near the perimeter of the substrate, leads to source material being deposited more heavily on feature sidewalls that face the center of the substrate than those that face the perimeter of the substrate.

Therefore, a need exists for improvements in the uniformity of depositing source materials across a substrate by PVD techniques.

### SUMMARY OF THE INVENTION

In one embodiment described herein a deposition apparatus comprises an electrically grounded chamber, a sputtering target supported by the chamber and electrically isolated from the chamber, a substrate support pedestal positioned below the sputtering target and having a substrate support surface substantially parallel to the sputtering surface of the sputtering target, a shield member supported by the chamber and electrically coupled to the chamber, and a collimator mechanically and electrically coupled to the shield member and positioned between the sputtering target and the substrate support pedestal. In one embodiment, the collimator has a plurality of apertures extending therethrough. In one embodiment, the apertures located in a central region have a higher aspect ratio than the apertures located in a peripheral region.

In another embodiment, a deposition apparatus comprises an electrically grounded chamber, a sputtering target supported by the chamber and electrically isolated from the chamber, a substrate support pedestal positioned below the sputtering target and having a substrate support surface substantially parallel to the sputtering surface of the sputtering target, a shield member supported by the chamber and electrically coupled to the chamber, a collimator mechanically and electrically coupled to the shield member and positioned between the sputtering target and the substrate support pedestal, a gas source, and a controller. In one embodiment, the sputtering target is electrically coupled to a DC power source. In one embodiment, the substrate support pedestal is electrically coupled to an RF power source. In one embodiment, the controller is programmed to provide signals to control the gas source, DC power source, and the RF power source. In one embodiment, the collimator has a plurality of apertures extending therethrough. In one embodiment the apertures located in a central region have a higher aspect ratio than the apertures located in a peripheral region of the collimator. In one embodiment, the controller is programmed to provide high bias to the substrate support pedestal.

In yet another embodiment, a method for depositing material onto a substrate comprises applying a DC bias to a sputtering target in a chamber having a collimator positioned between the sputtering target and a substrate support pedestal, providing a processing gas in a region adjacent the sputtering target within the chamber, applying a bias to the substrate support pedestal, and pulsing the bias applied to the substrate support pedestal between a high bias and a low bias. In one embodiment, the collimator has a plurality of apertures extending therethrough. In one embodiment, the apertures located in a central region have a higher aspect ratio than the apertures located in a peripheral region of the collimator.

In yet another embodiment, a collimator for mechanical and electrical coupling with a shield member positioned between a sputtering target and a substrate support pedestal is provided. The collimator comprises a central region and a peripheral region, wherein the collimator has a plurality of apertures extending therethrough and where the apertures located in the central region have a higher aspect ratio than the apertures located in the peripheral region.

In yet another embodiment, a lower shield for encircling a substrate support pedestal that faces a target in a substrate processing chamber is provided. The lower shield comprises a cylindrical outer band having a first diameter dimensioned to encircle a sputtering surface of the sputtering target and the substrate support pedestal, the outer cylindrical band comprising a top portion that surrounds a sputtering surface of the sputtering target, a middle portion, and a bottom portion that surrounds the substrate support pedestal, a support flange having a resting surface and extending radially outward from the cylindrical outer band, a base plate extending radially inward from the bottom portion of the cylindrical outer band, and a cylindrical inner band coupled with the base plate and partially surrounding a peripheral edge of the substrate support pedestal.

In yet another embodiment, an upper shield for encircling a sputtering target that faces a support pedestal in a substrate processing chamber is provided. The upper shield comprises a shield portion and an integrated flux optimizer for directional sputtering.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic sectional view of a semiconductor processing system having one embodiment of a process kit described herein;

FIG. 2 is a top plan view of a collimator according to one embodiment described herein;

FIG. 3 is a schematic, cross-sectional view of a collimator according to one embodiment described herein;

FIG. 4 is a schematic, cross-sectional view of a collimator according to one embodiment described herein;

FIG. 5 is a schematic, cross-sectional view of a collimator according to one embodiment described herein;

FIG. 6 is an enlarged, partial cross-sectional view of a bracket for attaching a collimator to an upper shield of a PVD chamber according to one embodiment described herein;

FIG. 7 is a partial cross-sectional view of a bracket for attaching a collimator to an upper shield of a PVD chamber according to one embodiment described herein;

FIG. 8 is a schematic sectional view of a semiconductor processing system having another embodiment of a process kit described herein;

FIG. 9A is a partial cross-sectional view of a monolithic upper shield according to one embodiment described herein;

FIG. 9B is a top plan view of the monolithic upper shield of FIG. 9A according to one embodiment described herein;

FIG. 10A is a cross-sectional view of a lower shield according to one embodiment described herein;

FIG. 10B is a partial sectional view of one embodiment of the lower shield of FIG. 10A; and

FIG. 10C is a top view of one embodiment of the lower shield of FIG. 10A.

### DETAILED DESCRIPTION

Embodiments described herein provide apparatus and methods for uniform deposition of sputtered material across high aspect ratio features of a substrate during the fabrication of integrated circuits on substrates.

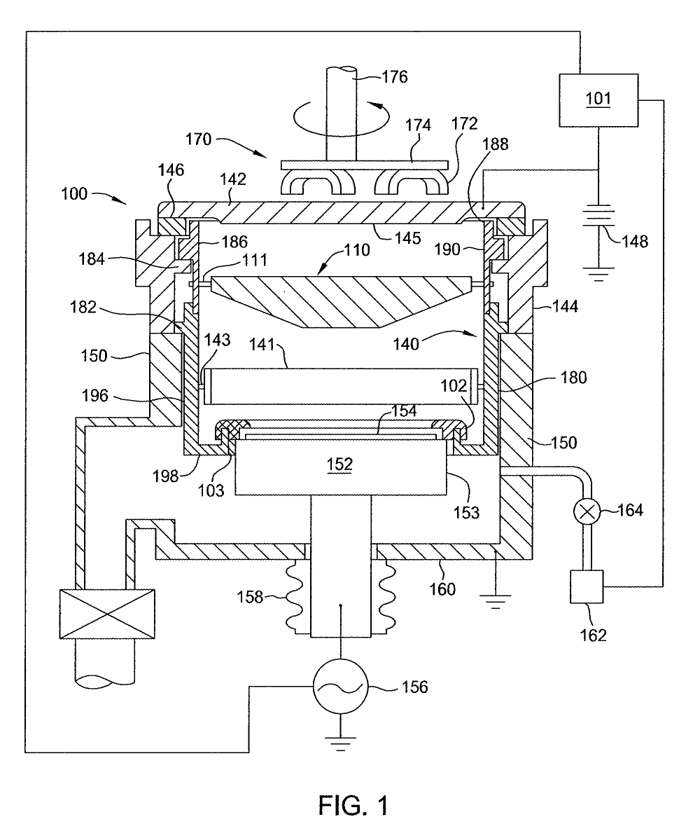

FIG. 1 depicts an exemplary embodiment of a processing chamber 100 having one embodiment of a process kit 140 capable of processing a substrate 154. The process kit 140 includes a one-piece lower shield 180, a one-piece upper shield 186, and a collimator 110. In the embodiment shown, the processing chamber 100 comprises a sputtering chamber, also called a physical vapor deposition (PVD) chamber, capable of depositing, for example, titanium, aluminum oxide, aluminum, copper, tantalum, tantalum nitride, tungsten, or tungsten nitride on a substrate. Examples of suitable PVD chambers include the ALPS® Plus and SIP ENCORE® PVD processing chambers, both commercially available from Applied Materials, Inc., Santa Clara, of Calif. It is contemplated that processing chambers available from other manufactures may also be utilized to perform the embodiments described herein.

The chamber 100 includes a sputtering source, such as a target 142 having a sputtering surface 145, and a substrate support pedestal 152, for receiving a semiconductor substrate 154 thereon, having a peripheral edge 153. The substrate support pedestal may be located within a grounded chamber wall 150.

In one embodiment, the chamber 100 includes the target 142 supported by a grounded conductive adapter 144 through a dielectric isolator 146. The target 142 comprises the material to be deposited on the substrate 154 surface during sputtering, and may include copper for depositing as a seed layer in high aspect ratio features formed in the substrate 154. In one embodiment, the target 142 may also include a bonded composite of a metallic surface layer of sputterable material, such as copper, and a backing layer of a structural material, such as aluminum.

In one embodiment, the pedestal 152 supports a substrate 154 having high aspect ratio features to be sputter coated, the bottoms of which are in planar opposition to a principal surface of the target 142. The substrate support pedestal 152 has a planar substrate-receiving surface disposed generally parallel to the sputtering surface of the target 142. The pedestal 152 may be vertically movable through a bellows 158 connected to a bottom chamber wall 160 to allow the substrate 154 to be transferred onto the pedestal 152 through a load lock valve (not shown) in a lower portion of the chamber 100. The pedestal 152 may then be raised to a deposition position as shown.

In one embodiment, processing gas may be supplied from a gas source 162 through a mass flow controller 164 into the lower portion of the chamber 100. In one embodiment, a controllable direct current (DC) power source 148, coupled to the chamber 100, may be used to apply a negative voltage or bias to the target 142. A radio frequency (RF) power source 156 may be coupled to the pedestal 152 to induce a DC self-bias on the substrate 154. In one embodiment, the pedestal 152 is grounded. In one embodiment, the pedestal 152 is electrically floated.

In one embodiment, a magnetron 170 is positioned above the target 142. The magnetron 170 may include a plurality of magnets 172 supported by a base plate 174 connected to a shaft 176, which may be axially aligned with the central axis of the chamber 100 and the substrate 154. In one embodiment, the magnets are aligned in a kidney-shaped pattern. The magnets 172 produce a magnetic field within the chamber 100 near the front face of the target 142 to generate plasma, such that a significant flux of ions strike the target 142, causing sputter emission of target material. The magnets 172 may be rotated about the shaft 176 to increase uniformity of the magnetic field across the surface of the target 142. In one embodiment, the magnetron 170 is a small magnet magnetron. In one embodiment, the magnets 172 may be both rotated and moved reciprocally in a linear direction substantially parallel to the face of the target 142 to produce a spiral motion. In one embodiment, the magnets 172 may be rotated about both a central axis and an independently-controlled secondary axis to control both their radial and angular positions.

In one embodiment, the chamber 100 includes a grounded lower shield 180 having a support flange 182 supported by and electrically coupled to the chamber sidewall 150. An upper shield 186 is supported by and electrically coupled to a flange 184 of the adapter 144. The upper shield 186 and the lower shield 180 are electrically coupled as are the adapter 144 and the chamber wall 150. In one embodiment, both the upper shield 186 and the lower shield 180 are comprised of stainless steel. In one embodiment, the chamber 100 includes a middle shield (not shown) coupled to the upper shield 186. In one embodiment, the upper shield 186 and lower shield 180 are electrically floating within the chamber 100. In one embodiment, the upper shield 186 and lower shield 180 may be coupled to an electrical power source.

In one embodiment, the upper shield 186 has an upper portion that closely fits an annular side recess of the target 142 with a narrow gap 188 between the upper shield 186 and the target 142, which is sufficiently narrow to prevent plasma from penetrating and sputter coating the dielectric isolator 146. The upper shield 186 may also include a downwardly projecting tip 190, which covers the interface between the lower shield 180 and the upper shield 186, preventing them from being bonded by sputter deposited material.

In one embodiment, the lower shield 180 extends downwardly into a cylindrical outer band 196, which generally extends along the chamber wall 150 to below the top surface of the pedestal 152. The lower shield 180 may have a base plate 198 extending radially inward from the cylindrical outer band 196. The base plate 198 may include an upwardly extending cylindrical inner band 103 surrounding the perimeter of the pedestal 152. In one embodiment, a cover ring 102 rests on the top of the cylindrical inner band 103 when the pedestal 152 is in a lower, loading position and rests on the outer periphery of the pedestal 152 when the pedestal is in an upper, deposition position to protect the pedestal 152 from sputter deposition.

The lower shield 180 encircles the sputtering surface 145 of the sputtering target 142 that faces the support pedestal 152 and also encircles a peripheral wall of the support pedestal 152. The lower shield 160 covers and shadows the chamber wall 150 of the chamber 100 to reduce deposition of sputtering deposits originating from the sputtering surface 145 of the sputtering target 142 onto the components and surfaces behind the lower shield 180. For example, the lower shield 180 can protect the surfaces of the support pedestal 152, portions of the substrate 154, the chamber wall 150, and the bottom wall 160 of the chamber 100.

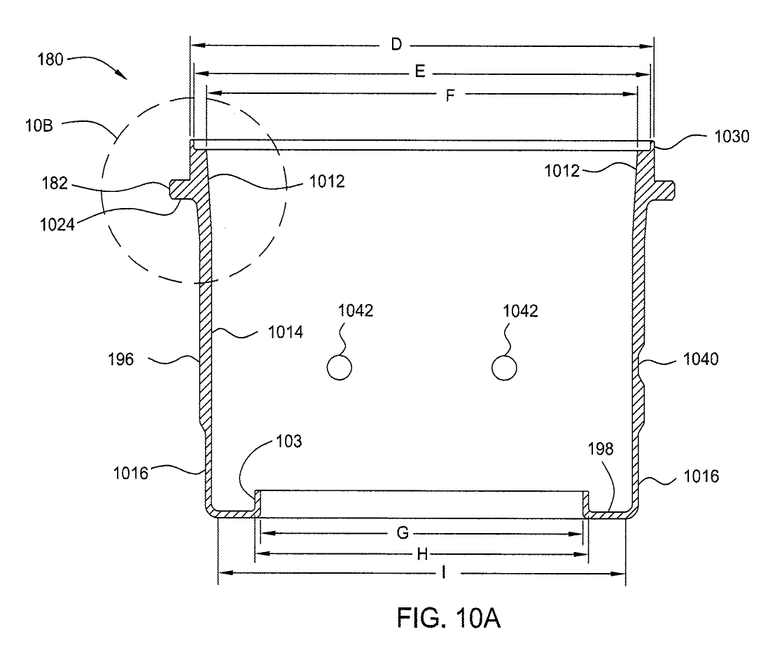

In one embodiment, directional sputtering may be achieved by positioning the collimator 110 between the target 142 and the substrate support pedestal 152. The collimator 110 may be mechanically and electrically coupled to the upper shield 186. In one embodiment, the collimator 110 may be coupled to a middle shield (not shown), positioned lower in the chamber 100. In one embodiment, the collimator 110 is integral to the upper shield 186, as shown in FIG. 8. In one embodiment, the collimator 110 is welded to the upper shield 186. In one embodiment, the collimator 110 may be electrically floating within the chamber 100. In one embodiment, the collimator 110 may be coupled to an electrical power source. The collimator 110 includes a plurality of apertures (omitted from FIG. 1) to direct gas and/or material flux within the chamber.

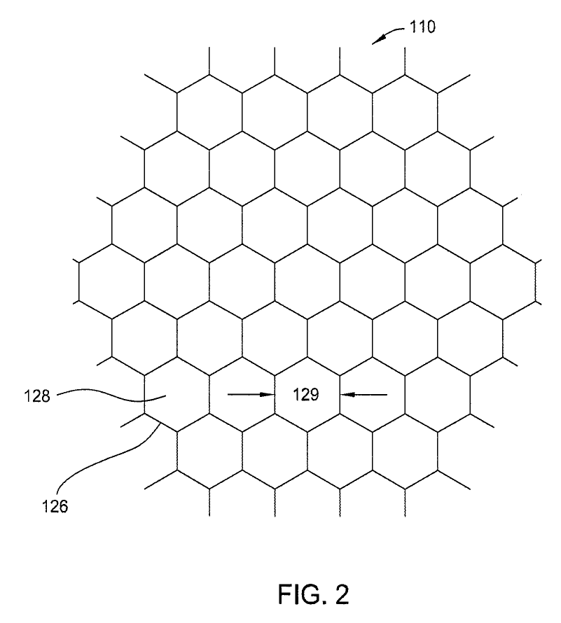

FIG. 2 is a top plan view of one embodiment of the collimator 110. The collimator 110 is generally a honeycomb structure having hexagonal walls 126 separating hexagonal apertures 128 in a close-packed arrangement. An aspect ratio of the hexagonal apertures 128 may be defined as the depth of the aperture 128 (equal to the thickness of the collimator) divided by the width 129 of the aperture 128. In one embodiment, the thickness of the walls 126 is between about 0.06 inches and about 0.18 inches. In one embodiment, the thickness of the walls 126 is between about 0.12 inches and about 0.15 inches. In one embodiment, the collimator 110 is comprised of a material selected from aluminum, copper, and stainless steel.

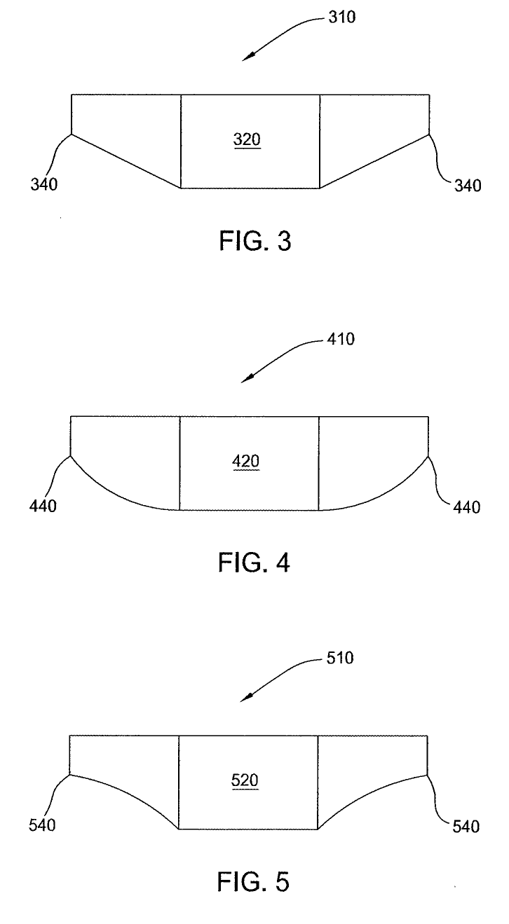

FIG. 3 is a schematic, cross-sectional view of a collimator 310 according to one embodiment described herein. The collimator 310 includes a central region 320 having a high aspect ratio, such as from about 1.5:1 to about 3:1. In one embodiment, the aspect ratio of the central region 320 is about 2.5:1. The aspect ratio of collimator 310 decreases along with the radial distance from the central region 320 to an outer peripheral region 340. In one embodiment, the aspect ratio of the collimator 310 decreases from a central region 320 aspect ratio of about 2.5:1 to a peripheral region 340 aspect ratio of about 1:1. In another embodiment, the aspect ratio of the collimator 310 decreases from a central region 320 aspect ratio of about 3:1 to a peripheral region 340 aspect ratio of about 1:1. In one embodiment, the aspect ratio of the collimator 310 decreases from a central region 320 aspect ratio of about 1.5:1 to a peripheral region 340 aspect ratio of about 1:1.

In one embodiment, the radial aperture decrease of the collimator 310 is accomplished by varying the thickness of the collimator 310. In one embodiment, the central region 320 of the collimator 310 has an increased thickness, such as between about 3 in to about 6 in. In one embodiment, the thickness of in the central region 320 of the collimator 310 is about 5 in. In one embodiment, the thickness of the collimator 310 decreases from the central region 320 to the outer peripheral region 340. In one embodiment, the thickness of the collimator 310 radially decreases from a central region 320 thickness of about 5 in to a peripheral region 340 thickness of about 2 in. In one embodiment, the thickness of the collimator 310 radially decreases from a central region 320 thickness of about 6 in to a peripheral region 340 thickness of about 2 in. In one embodiment, the thickness of the collimator 310 radially decreases from a central region 320 thickness of about 2.5 in to about 2 in.

Although the variance in the aspect ratio of the embodiment of collimator 310 depicted in FIG. 3 shows a radially decreasing thickness, the aspect ratio may alternatively be decreased by increasing the width of the apertures of the collimator 310 from the central region 320 to the peripheral region 340. In another embodiment, the thickness of the collimator 310 is decreased and the width of apertures of the collimator 310 is increased from the central region 320 to the peripheral region 340.

Generally, the embodiment in FIG. 3 depicts the aspect ratio radially decreasing in a linear fashion, resulting in an inverted conical shape. Other embodiments of the present invention may include non-linear decreases in the aspect ratio.

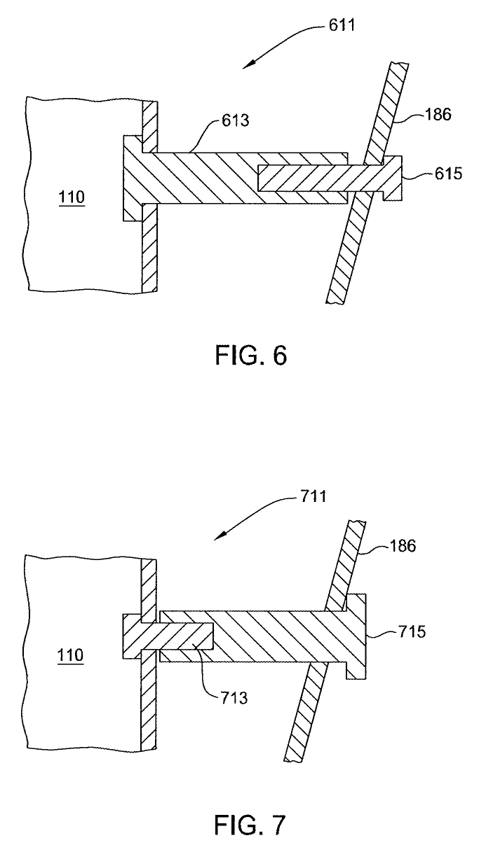

FIG. 4 is a schematic, cross-sectional view of a collimator 410 according to one embodiment of the present invention. The collimator 410 has a thickness that decreases from a central region 420 to a peripheral region 440 in a non-linear fashion, resulting in a convex shape.

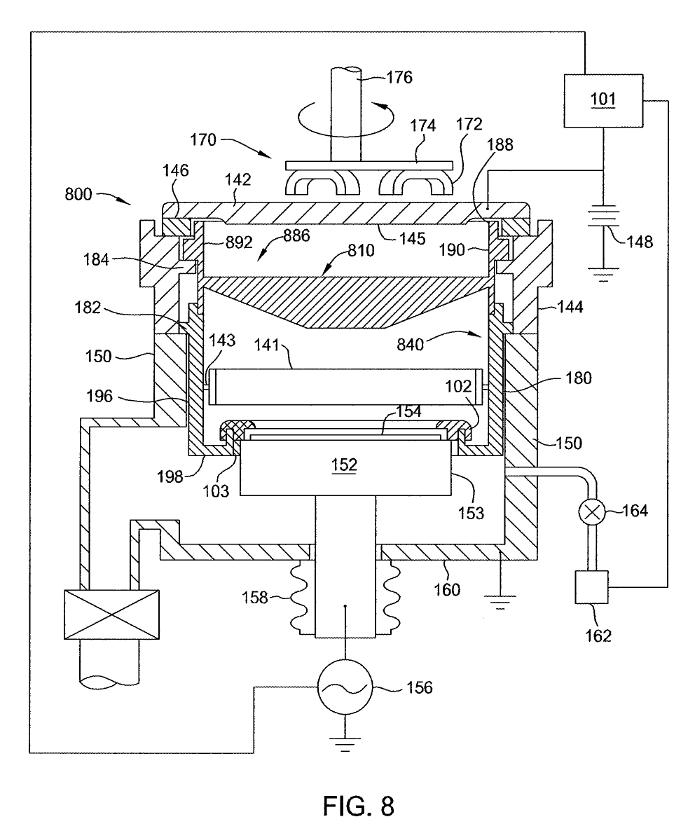

FIG. 5 is a schematic, cross-sectional view of a collimator 510 according to one embodiment of the present invention. The collimator 510 has a thickness that decreases from a central region 520 to a peripheral region 540 in a nonlinear fashion, resulting in a concave shape.

In some embodiments, the central region 320, 420, 520 approaches zero, such that the central region 320, 420, 520 appears as a point on the bottom of the collimator 310, 410, 510.

Referring back to FIG. 1, the operation of the PVD process chamber 100 and the function of the collimator 110 are similar regardless of the exact shape of the radial decreasing aspect ratio of the collimator 110. A system controller 101 is provided outside of the chamber 100 and generally facilitates control and automation of the overall system. The system controller 101 may include a central processing unit (CPU) (not shown), memory (not shown), and support circuits (not shown). The CPU may be one of any computer processors used in industrial settings for controlling various system functions and chamber processes.

In one embodiment, the system controller 101 provides signals to position the substrate 154 on the substrate support pedestal 152 and generate plasma in the chamber 100. The system controller 101 sends signals to apply a voltage via DC power source 148 to bias the target 142 and to excite processing gas, such as argon, into plasma. The system controller 101 may further provide signals to cause the RF power source 156 to DC self-bias the pedestal 152. The DC self-bias helps attract positively charged ions created in the plasma deeply into high aspect ratio vias and trenches on the surface of the substrate.

The collimator 110 functions as a filter to trap ions and neutrals that are emitted from the target 142 at angles exceeding a selected angle, near normal to the substrate 154. The collimator 110 may be one of the collimators 310, 410, or 510, depicted in FIGS. 3, 4, or 5, respectively. The characteristic of the collimator 110 of having an aspect ratio that decreases radially from the center allows a greater percentage of ions emitted from peripheral regions of the target 142 to pass through the collimator 110. As a result, both the number of ions and the angle of arrival of ions deposited onto peripheral regions of the substrate 154 are increased. Therefore, according to embodiments of the present invention, material may be more uniformly sputter deposited across the surface of the substrate 154. Additionally, material may be more uniformly deposited on the bottom and sidewalls of high aspect ratio features, particularly high aspect ratio vias and trenches located near the periphery of the substrate 154.

Additionally, in order to provide even greater coverage of sputter deposited material onto the bottom and sidewalls of high aspect ratio features, material sputter deposited onto the field and bottom regions of features may be sputter etched. In one embodiment, the system controller 101 applies a high bias to the pedestal 152 such that the target 142 ions etch film already deposited on the substrate 154. As a result, the field deposition rate onto the substrate 154 is reduced, and the sputtered material re-deposits on either the sidewalls or bottom of the high aspect ratio features. In one embodiment, the system controller 101 applies high and low bias to the pedestal 152 in a pulsing, or alternating fashion such that the process becomes a pulsing deposit/etch process. In one embodiment, the collimator 110 cells specifically located below magnets 172 direct the majority of the deposition material toward the substrate 154. Therefore, at any particular time, material in one region of the substrate 154 may be deposited, while material already deposited in another region of the substrate 154 may be etched.

In one embodiment, to provide even greater coverage of sputter deposited material onto the sidewalls of high aspect ratio features, material sputter deposited onto the bottom of the features may be sputter etched using secondary plasma, such as argon plasma, generated in a region of the chamber 100 near the substrate 154. In one embodiment, the chamber 100 includes an RF coil 141 attached to the lower shield 180 by a plurality of coil standoffs 143, which electrically insulate the coil 141 from the lower shield 180. The system controller 101 sends signals to apply RF power through the shield 180 to the coil 141 via feedthrough standoffs (not shown). In one embodiment, the RF coil inductively couples RF energy into the interior of the chamber 100 to ionize precursor gas, such as argon, to maintain secondary plasma near the substrate 154. The secondary plasma resputters a deposition layer from the bottom of a high aspect ratio feature and redeposits the material onto the sidewalls of the feature.

Still referring to FIG. 1, the collimator 110 may be attached to the upper shield 186 by a plurality of radial brackets 111.

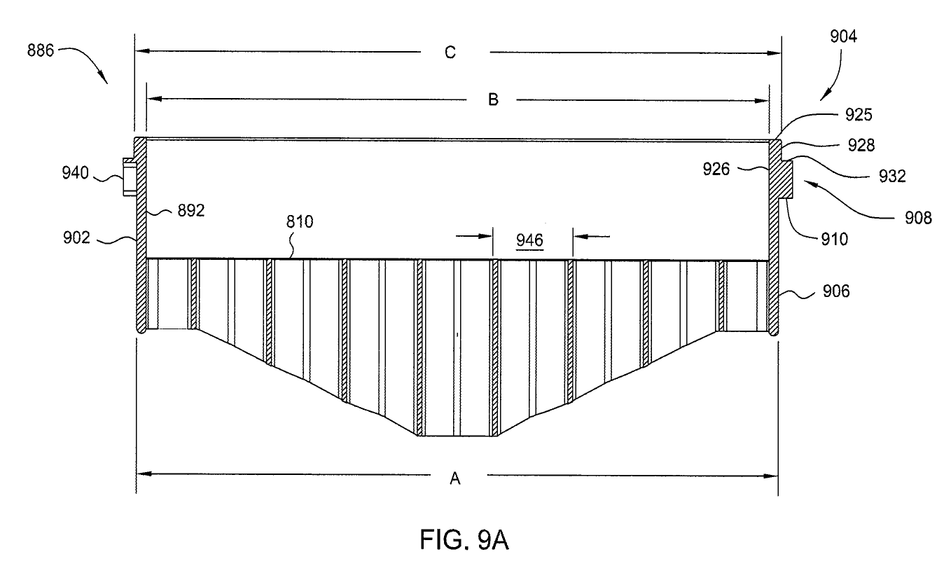

FIG. 6 is an enlarged, cross-sectional view of a bracket 611 for attaching the collimator 110 to the upper shield 186 according to one embodiment of the present invention. The bracket 611 includes an internally threaded tube 613 that is welded to the collimator 110 and extends radially outward therefrom. A fastening member 615, such as a screw, may be inserted through an aperture in the upper shield 186 and threaded into the tube 613 to attach the collimator 110 to the upper shield 186, while minimizing the potential for depositing material onto the threaded portion of the tube 613 or the fastening member 615.

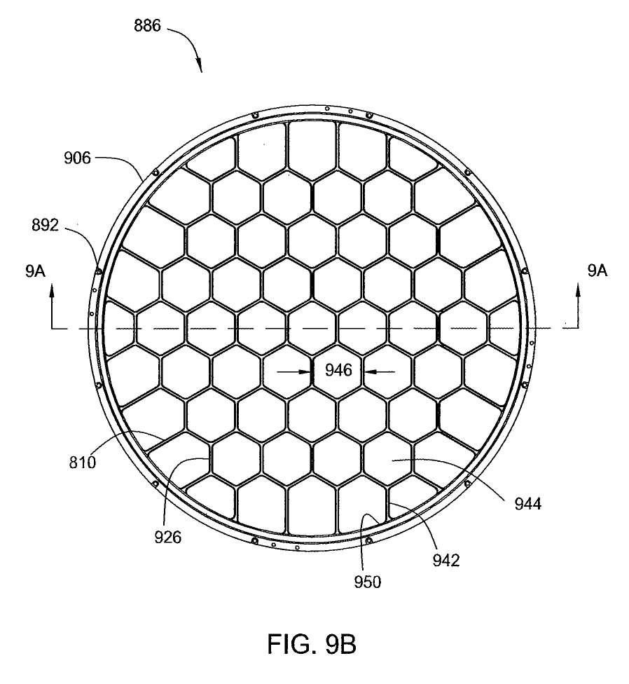

FIG. 7 is an enlarged, cross-sectional view of a bracket 711 for attaching the collimator 110 to the upper shield 186 according to another embodiment of the present invention. The bracket 711 includes a stud 713 that is welded to the collimator 110 and extends radially outward therefrom. An internally threaded fastening member 715 may be inserted through an aperture in the upper shield 186 and threaded onto the stud 713 to attach the collimator 110 to the upper shield 186, while minimizing the potential for depositing material onto threaded portions of the stud 713 or the fastening member 715.

FIG. 8 is a schematic sectional view of a semiconductor processing system 800 having another embodiment of a process kit 840 described herein. Similar to process kit 140, the process kit 840 includes a one-piece lower shield 180. However, unlike the process kit 140 which comprises a separate collimator 110 coupled with the upper shield 186 via a radial bracket 111, the process kit 840 includes a monolithic upper shield 886 comprising a shield portion 892 and an integrated flux optimizer portion 810. The monolithic construction of the monolithic upper shield 886 allows for maximization of cooling efficiency. The integrated flux optimizer portion 810 includes a plurality of apertures (omitted from FIG. 8) to direct gas and/or material flux within the chamber as discussed above.

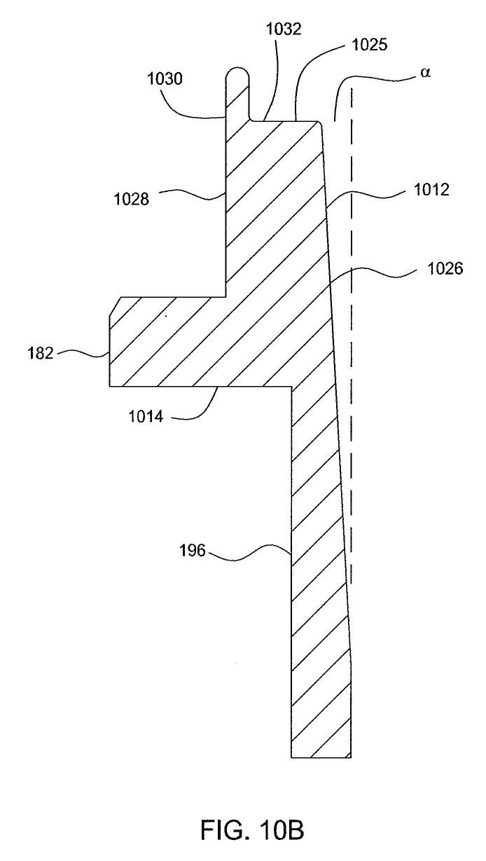

FIG. 9A is a partial cross-sectional view of a monolithic upper shield 886 according to one embodiment described herein. FIG. 9B is a top plan view of the monolithic upper shield 886 of FIG. 9A according to one embodiment described herein. The monolithic upper shield 886 is dimensioned to encircle the sputtering surface 145 of the sputtering target 142 that faces the support pedestal 152. The monolithic upper shield 886 shadows the adapter 144 of the chamber 100 to reduce deposition of sputtering deposits originating from the sputtering surface 145 of the sputtering target 142.

As shown in FIGS. 8, 9A, and 9B, the monolithic upper shield 886 is of unitary construction and comprises a shield portion 892 and an integrated flux optimizer portion 810. For example, the shield portion 892 and the integrated flux optimizer portion 810 may be fabricated from a single mass of material. The shield portion 892 comprises a cylindrical band 902. The cylindrical band 902 comprises a top wall 904 and a bottom wall 906. A support flange 908 extends radially outward from the top wall 904 of the cylindrical band 902. The support flange 908 comprises a resting surface 910 for resting upon the adapter 144 of the chamber 800. In one embodiment, the resting surface 910 intersects with the bottom wall 906 forming a 90 degree angle. In one embodiment, the support flange 908 has a plurality of slots shaped to receive a pin to align the upper shield 892 with the adapter 144. In one embodiment the support flange 908 has one or more notches 940 positioned periodically around the cylindrical band 902.

As shown in FIG. 9A, the top wall 904 further comprises a top surface 925, an inner periphery 926, and an outer periphery 928. The outer periphery 928 of the top wall 904 intersects with the support flange 908 to form a stepped portion 932.

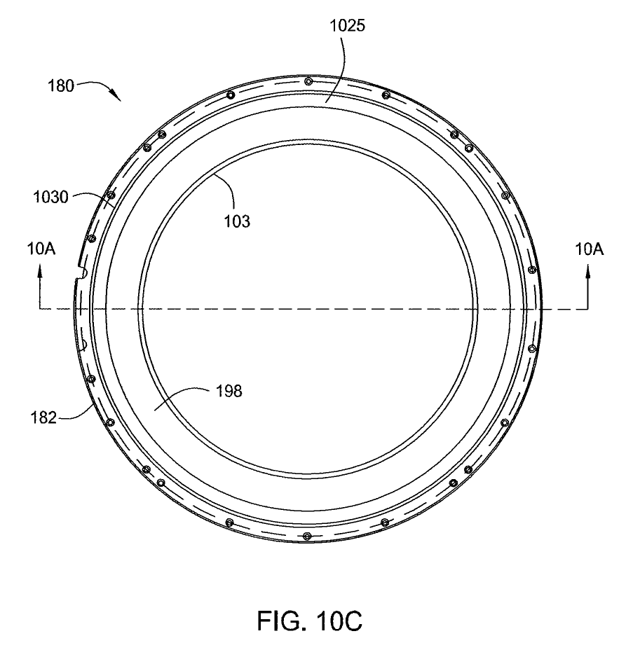

In one embodiment, as shown in FIG. 8, the bottom wall 906 of the cylindrical band 902 has an outer diameter shown by arrows “A” dimensioned to fit within the adapter 144 and rest on a stepped portion 1032 (shown in FIG. 10B) of the lower shield 180. In one embodiment, the outer diameter “A” of the bottom wall 906 is between about 18 inches (45.7 cm) and about 18.5 inches (47 cm). In another embodiment, the outer diameter “A” of the bottom wall 906 is between about 18.1 inches (46 cm) and about 18.2 inches (46.2 cm). In one embodiment, the cylindrical band 902 has an inner diameter shown by arrows “B”. In one embodiment, the inner diameter “B” of the cylindrical band 902 is between about 17.2 inches (43.7 cm) and about 17.9 inches (45.5 cm). In another embodiment, the inner diameter “B” of the cylindrical band 902 is between about 17.5 inches (44.5 cm) and about 17.7 inches (45 cm). In one embodiment, the top wall 904 has an outer diameter shown by arrows “C”. In one embodiment, the top wall 904 and the bottom wall 906 have the same inner diameter “B”.

In one embodiment, the outer diameter “C” of the top wall 904 is between about 18 inches (45.7 cm) and about 18.5 inches (47 cm). In another embodiment, the outer diameter “C” of the top wall 904 is between about 18.3 inches (46.5 cm) and about 18.4 inches (46.7 cm). In one embodiment, the outer diameter “C” of the top wall 904 is greater than the outer diameter “A” of the bottom wall 906.

The integrated flux optimizer portion 810 may be designed similarly to one of the collimators 310, 410, or 510 depicted in FIGS. 3, 4, and 5 respectively. As shown in FIG. 9B, the integrated flux optimizer portion 810 is generally a honeycomb structure having hexagonal walls 942 separating hexagonal apertures 944 in a close-packed arrangement. An aspect ratio of the hexagonal apertures 944 may be defined as the depth of the aperture 944 (equal to the thickness off the integrated flux optimizer portion 810 divided by the width 946 of the aperture. In one embodiment, the hexagonal walls 942 adjacent to the shield portion 892 have a chamfer 950 and a radius.

In one embodiment, the monolithic upper shield 886 may be machined from a single mass of aluminum. The monolithic upper shield 886 may optionally be coated or anodized. Alternatively, the monolithic upper shield 886 may be made from other materials compatible with the processing environment, and may also be comprised of one or more sections. Alternatively, the shield portion 892 and the integrated flux optimizer portion 810 of the upper shield may are formed as separate pieces and coupled together using suitable attachment means, such as welding.

FIGS. 10A and 10B are partial sectional views of a lower shield according to embodiments described herein. FIG. 10C is a top view of one embodiment of the lower shield of FIG. 10A. As shown in FIG. 1 and FIGS. 10A-10C, the lower shield 180 is of unitary construction and comprises a cylindrical outer band 196, a base plate 198, and an inner cylindrical band 103. The cylindrical outer band 196 has a diameter dimensioned to encircle the sputtering surface 145 of the sputtering target 142 and the peripheral edge 153 of the pedestal 152. The cylindrical outer band 196 comprises an upper portion 1012, a middle portion 1014, and a lower portion 1016. The upper portion 1012 is dimensioned to encircle the sputtering surface 145 of the sputtering target 142. A support flange 182 extends radially outward from the upper portion 1012 of the cylindrical outer band 196. The support flange 182 comprises a resting surface 1024 to rest upon the chamber walls 150 of the chamber 100. The resting surface 1024 may have a plurality of slots shaped to receive a pin to align the lower shield 180 to the chamber walls 150 or any adapters positioned between the chamber walls 150 and the lower shield 180. In one embodiment, the resting surface 1024 has a surface roughness of from about 10 to about 80 microinches, or even from about 16 to about 63 microinches, or in one embodiment an average surface roughness of about 32 microinches.

As shown in FIG. 10B, the upper portion 1012 comprises a top surface 1025, an inner periphery 1026, and an outer periphery 1028. The outer periphery 1028 extends upward above the top surface 1025 forming an annular lip 1030. The annular lip 1030 forms a stepped portion 1032 with the top surface 1025. In one embodiment, the annular lip 1030 is positioned perpendicular to the top surface 1025 to form the stepped portion 1032. The stepped portion 1032 provides a resting surface for interfacing with the upper shield 186.

In one embodiment, the annular lip 1030 has an outer diameter shown by arrows “D”. In one embodiment, the outer diameter “D” of the annular lip 1030 is between about 18.4 inches (46.7 cm) and about 18.7 inches (47.5 cm). In another embodiment, the outer diameter “D” of the annular lip 1030 is between about 18.5 inches (47 cm) and about 18.6 inches (47.2 cm). In one embodiment, the annular lip 1030 has an inner diameter shown by arrows “E”. In one embodiment, the inner diameter “E” of the annular lip 1030 is between about 18.2 inches (46.2 cm) and about 18.5 inches (47 cm). In another embodiment, the inner diameter “E” of the annular lip 1030 is between about 18.3 inches (46.5 cm) and about 18.4 inches (46.7 cm).

In one embodiment, an outer diameter of the top surface 1025 is identical to the inner diameter of the “E” of the annular lip 1030. In one embodiment, the top surface has an inner diameter shown by arrows “F”. In one embodiment, the inner diameter “F” of the top surface 1025 is between about 17.2 inches (43.7 cm) and about 18 inches (45.7 cm). In another embodiment, the inner diameter “F” of the top surface 1025 is between about 17.5 inches (44.5 cm) and about 17.6 inches (44.7 cm).

In one embodiment, the inner periphery 1026 of the upper portion 1012 is angled radially outward at an angle α from vertical. In one embodiment, the angle α is from about 2 degrees to about 10 degrees from vertical. In one embodiment, the angle α is about 4 degrees from vertical.

The lower portion 1016 is dimensioned to encircle the pedestal 152. The base plate 198 extends radially inward from the lower portion 1016 of the cylindrical outer band 196. The cylindrical inner band 103 is coupled with the base plate 198 and is dimensioned to encircle the pedestal 152. The cylindrical inner band 103, the base plate 198, and the cylindrical outer band 196 form a U-shaped channel. The cylindrical inner band 103 comprises a height that is less than the height of the cylindrical outer band 196. In one embodiment, the height of the inner cylindrical band 103 is about one fifth of the height of the cylindrical outer band 196. In one embodiment, the middle portion 1014 has a notch 1040. In one embodiment, the cylindrical outer band 196 has a plurality of gas holes 1042.

In one embodiment, the base plate 198 has an outer diameter shown by arrows “G”. In one embodiment, the outer diameter “G” of the base plate 198 is between about 17 inches (43.2 cm) and about 17.4 inches (44.2 cm). In another embodiment, the outer diameter “G” of the base plate 198 is between about 17.1 inches (43.4 cm) and about 17.2 inches (43.7 cm). In one embodiment, the base plate 198 has an inner diameter shown by arrows “I”. In one embodiment, the inner diameter “I” of the base plate 198 is between about 13.9 inches (35.3 cm) and about 14.4 inches (36.6 cm). In another embodiment, the inner diameter “I” of the base plate 198 is between about 14 inches (35.6 cm) and about 14.1 inches (35.8 cm).

In one embodiment, the inner cylindrical band 103 has an outer diameter shown by arrows “H”. In one embodiment, the outer diameter “H” of the inner cylindrical band is between about 14.0 inches (35.6 cm) and about 14.3 inches (36.3 cm). In another embodiment, the outer diameter “H” of the inner cylindrical band 103 is between about 14.2 inches (36.1 cm) and about 14.3 inches (36.3 cm).

In one embodiment, the cylindrical outer band 196, the base plate 198, and the inner cylindrical band 103 comprise a unitary structure. A unitary lower shield 180 is advantageous over prior shields which included multiple components, often two or three separate pieces to make up the complete lower shield. For example, a single piece shield is more thermally uniform than a multiple-component shield, in both heating and cooling processes. For example, the single piece lower shield 180 has only one thermal interface to the chamber wall 150, allowing for more control over the heat exchange between the shield 180 and chamber wall 150. A shield 180 with multiple components makes it more difficult and laborious to remove the shield for cleaning. The single piece shield 180 has a continuous surface exposed to the sputtering deposits without interfaces or corners that are more difficult to clean out. The single piece shield 180 also more effectively shields the chamber wall 150 from sputter deposition during process cycles.

In one embodiment, the upper shields 186, 886 and/or the lower shield 180 can be made from 300 series stainless steel, or in another embodiment, aluminum. In one embodiment, the exposed surfaces of the upper shields 186, 886 and/or the lower shield 180 are treated with CLEANCOAT™, which is commercially available from Applied Materials, Santa Clara, Calif. CLEANCOAT™ is a twin-wire aluminum arc spray coating that is applied to substrate processing chamber components, such as the upper shields 186, 886 and/or the lower shield 180, to reduce particle shedding of deposits on the shields and thus prevent contamination of a substrate in the chamber. In one embodiment, the twin-wire aluminum arc spray coating on the upper shields 186, 886 and/or the lower shield 180 has a surface roughness of from about 600 to about 2300 microinches.

The upper shields 186, 886 and/or the lower shield 180 have exposed surfaces facing the interior volume in the chamber 100, 800. In one embodiment, the exposed surfaces are bead blasted to have a surface roughness of 175±75 microinches. The texturized bead blasted surfaces serve to reduce particle shedding and prevent contamination within the chamber 100, 800. The surface roughness average is the mean of the absolute values of the displacements from the mean line of the peaks and valleys of the roughness features along the exposed surface. The roughness average, skewness, or other properties may be determined by a profilometer that passes a needle over the exposed surface and generates a trace of the fluctuations of the height of the asperities on the surface, or by a scanning electron microscope that uses an electron beam reflected from the surface to generate an image of the surface.

While the foregoing is directed to embodiments of the present invention, other and further embodiments of the invention may be devised without departing from the basic scope thereof, and the scope thereof is determined by the claims that follow.

What is claimed is:

1. A collimator for mechanical and electrical coupling with a shield member positioned between a sputtering target and a substrate support pedestal, comprising:
a central region; and
a peripheral region, wherein the collimator has a plurality of apertures extending therethrough and wherein the apertures located in the central region have an aspect ratio higher than the apertures located in the peripheral region.

2. The collimator of claim 1, wherein a thickness of the collimator is greater in the central region than in the peripheral region.

3. The collimator of claim 1, wherein the aspect ratio of the apertures decreases continuously from the central region to the peripheral region.

4. The collimator of claim 3, wherein a thickness of the collimator continuously decreases from the central region to the peripheral region.

5. The collimator of claim 1, wherein the aspect ratio of the apertures decreases linearly from the central region to the peripheral region.

6. The collimator of claim 5, wherein a thickness of the collimator decreases linearly from the central region to the peripheral region.

7. The collimator of claim 1, wherein the aspect ratio of the apertures decreases nonlinearly from the central region to the peripheral region.

8. The collimator of claim 7, wherein a thickness of the collimator decreases nonlinearly from the central region to the peripheral region.

9. The collimator of claim 1, further comprising a bracket for coupling the collimator with the shield member, the bracket comprising:
an externally threaded member; and
an internally threaded member engaged with the externally threaded member.

10. A lower shield for encircling a substrate support pedestal that faces a sputtering target in a substrate processing chamber, comprising:
a cylindrical outer band having a first diameter dimensioned to encircle the sputtering surface of the sputtering target and the substrate support pedestal, the outer cylindrical band comprising:
a top portion that surrounds a sputtering surface of the sputtering target;
a middle portion; and
a bottom portion that surrounds the substrate support pedestal;
a support ledge having a resting surface and extending radially outward from the cylindrical outer band;
a base plate extending radially inward from the bottom portion of the cylindrical outer band; and
a cylindrical inner band coupled with the base plate and partially surrounding a peripheral edge of the substrate support pedestal.

11. The lower shield of claim 10, wherein the top portion comprises:
a top surface
an inner periphery; and
an outer periphery, wherein the outer periphery extends upward above the top surface to form an annular lip, the annular lip forming a stepped portion with the top surface for interfacing with the upper shield.

12. The lower shield of claim 11, wherein the inner periphery of the upper portion is angled between about 2 degrees and about 10 degrees from vertical.

13. The lower shield of claim 10, wherein the cylindrical inner band, the base plate, and the cylindrical outer band form a U-shaped channel.

14. The lower shield of claim 13, wherein the cylindrical inner band comprises a height that is less than the height of the cylindrical outer band.

15. The shield of claim 14, wherein the height of the cylindrical inner band is about one fifth of the height of the cylindrical outer band.

16. The lower shield of claim 10, wherein the cylindrical outer band, the top wall, the support ledge, the bottom wall, and the inner cylindrical band comprise a unitary structure.

17. An upper shield for encircling a sputtering target that faces a support pedestal in a substrate processing chamber, comprising:
a shield portion; and
an integrated flux optimizer for directional sputtering.

18. The upper shield of claim 17, wherein the integrated flux optimizer comprises:
a central region; and
a peripheral region, wherein the integrated flux optimizer has a plurality of apertures extending therethrough and wherein the apertures located in the central region have a higher aspect ratio than the apertures located in the peripheral region.

19. The upper shield of claim 18, wherein the thickness of the integrated flux optimizer is greater in the central region than in the peripheral region.

20. The upper shield of claim 18, wherein the aspect ratio of the apertures decreases continuously from the central region to the peripheral region.

21. The upper shield of claim 20, wherein a thickness of the integrated flux optimizer continuously decreases from the central region to the peripheral region.

22. The upper shield of claim 18, wherein the aspect ratio of the apertures decreases linearly from the central region to the peripheral region.

23. The upper shield of claim 22, wherein a thickness of the integrated flux optimizer decreases linearly from the central region to the peripheral region.

24. The upper shield of claim 18, wherein the aspect ratio of the apertures decreases nonlinearly from the central region to the peripheral region and a thickness of the collimator decreases nonlinearly from the central region to the peripheral region.

25. The upper shield of claim 18, wherein the shield portion and the integrated flux optimizer are machined from a single mass of aluminum.
